(19) United States
(12) Patent Application Publication
(10) Pub. No.: US 2026/0089956 A1
(43) Pub. Date: Mar. 26, 2026

(54) SEMICONDUCTOR DEVICE AND METHOD FOR FABRICATING THE SEMICONDUCTOR DEVICE

(71) Applicant: SK hynix Inc., Icheon-si Gyeonggi-do (KR)

(72) Inventors: Hee Do NA, Icheon-si Gyeonggi-do (KR); Sun Kak HWANG, Icheon-si Gyeonggi-do (KR); Sung Soon KIM, Icheon-si Gyeonggi-do (KR)

(73) Assignee: SK hynix Inc., Icheon-si Gyeonggi-do (KR)

(21) Appl. No.: 19/407,208

(22) Filed: Dec. 3, 2025

Related U.S. Application Data
(63) Continuation of application No. 17/411,796, filed on Aug. 25, 2021.

(30) Foreign Application Priority Data
Oct. 19, 2020 (KR) 10-2020-0135081

(51) Int. Cl. H10B 43/27; H10B 43/10; H10B 43/30

(52) U.S. Cl. CPC H10B 43/27; H10B 43/10; H10B 43/30

(57) ABSTRACT

The technology relates to a semiconductor device and a method for manufacturing the semiconductor device. According to the technology, a method for manufacturing a semiconductor device may comprise forming a gapfill target structure on a semiconductor substrate, the gapfill target structure including a horizontal recess parallel with the semiconductor substrate and having a first surface and a vertical slit extending from the horizontal recess and having a second surface perpendicular to the semiconductor substrate, removing a native oxide from the first surface to form a pre-cleaned first surface, forming, in-situ, a first semiconductor material on the pre-cleaned first surface and forming a second semiconductor material on the first semiconductor material.

### CROSS-REFERENCE TO RELATED APPLICATIONS

The present application is a continuation application of U.S. 17/411,796, filed on August 25, 2021, which claims priority under 35 U.S.C. §119(a) to Korean Patent Application No. 10-2020-0135081, filed on October 19, 2020, in the Korean Intellectual Property Office, which applications are incorporated herein by reference in their entirety.

### BACKGROUND

### 1. Technical Field

The disclosure relates to semiconductor devices, and more specifically, to semiconductor devices and methods for manufacturing the semiconductor devices.

### 2. Related Art

Manufacturing electronic devices, such as semiconductor devices, require a gapfill for a three-dimensional structure or high aspect ratio structure. The gapfill of the high aspect ratio structure is performed in the manufacture of, e.g., vertical semiconductor devices.

### SUMMARY

According to an embodiment of the disclosure, a method for manufacturing a semiconductor device may comprise forming a gapfill target structure on a semiconductor substrate, the gapfill target structure including a horizontal recess parallel with the semiconductor substrate and having a first surface and a vertical slit extending from the horizontal recess and having a second surface perpendicular to the semiconductor substrate; removing a native oxide from the first surface to form a pre-cleaned first surface; forming, in-situ, a first semiconductor material on the pre-cleaned first surface; and forming a second semiconductor material on the first semiconductor material.

According to an embodiment of the disclosure, a method for manufacturing a semiconductor device may comprise forming a lower level stack on a semiconductor substrate, the lower level stack including a source sacrificial layer and a source layer; forming an alternate stack on the lower level stack, the alternate stack including insulation layers and sacrificial layers; forming a vertical channel structure including a channel layer penetrating the alternate stack and the lower level stack; forming a slit exposing the source sacrificial layer and penetrating the alternate stack; forming a sealing layer on a side wall of the slit; forming a horizontal recess extending from the slit by removing the source sacrificial layer; exposing a portion of the channel layer from the horizontal recess; exposing an exposed surface of the channel layer to a pre-cleaning process of halogen gas; and selectively growing, in-situ, a polysilicon layer on the exposed surface of the channel layer after the pre-cleaning process.

According to an embodiment of the disclosure, a semiconductor device may comprise an alternate stack including insulation layers and gate electrodes alternately stacked one over another, on a semiconductor substrate; a source channel contact layer between the semiconductor substrate and the alternate stack; a vertical channel layer penetrating the alternate stack and the source channel contact layer; and a memory layer between the vertical channel layer and the alternate stack, wherein the source channel contact layer includes an epitaxial polysilicon layer contacting the vertical channel layer; and an amorphous silicon layer on the epitaxial polysilicon layer.

### BRIEF DESCRIPTION OF THE DRAWINGS

FIGS. 1 and 2 are views illustrating a vertical semiconductor device according to an embodiment.

FIGS. 3, 4, 5, 6, 7, 8, 9, 10, 11, 12, 13, 14, 15, 16, and 17, are views illustrating an example method for manufacturing a vertical semiconductor device according to an embodiment.

FIGS. 18, 19, 20, and 21, are views illustrating a method for manufacturing a vertical semiconductor device according to an embodiment.

FIG. 22A is a view illustrating a method for manufacturing a vertical semiconductor device according to a comparative example.

FIG. 22B is a view illustrating the results of secondary ion mass spectrometry (SIMS) analysis according to a comparative example.

FIG. 23 is a view illustrating the results of SIMS analysis according to an embodiment.

### DETAILED DESCRIPTION

Hereinafter, embodiments of the disclosure are described with reference to schematic cross-sectional views, plan views, or block diagrams. Changes or modifications may be made to the views depending on manufacturing techniques and/or tolerances. Thus, embodiments of the disclosure are not limited to specific types as shown and illustrated herein but may rather encompass changes or modifications resultant from fabricating processes. For example, the regions or areas shown in the drawings may be schematically shown, and their shapes shown are provided merely as examples, rather as limiting the category or scope of the disclosure.

Embodiments of the disclosure may provide a vertical semiconductor device with better reliability and a method for manufacturing the vertical semiconductor device.

According to the present technology, since native oxides on the surface of the channel layer are removed by a cleaning process using halogen gas, high and uniform current may be secured.

According to the present technology, since the polysilicon layer is selectively grown as the source channel contact layer, it may be possible to prevent phosphorus from accumulating at the interface between the channel layer and the source channel contact layer.

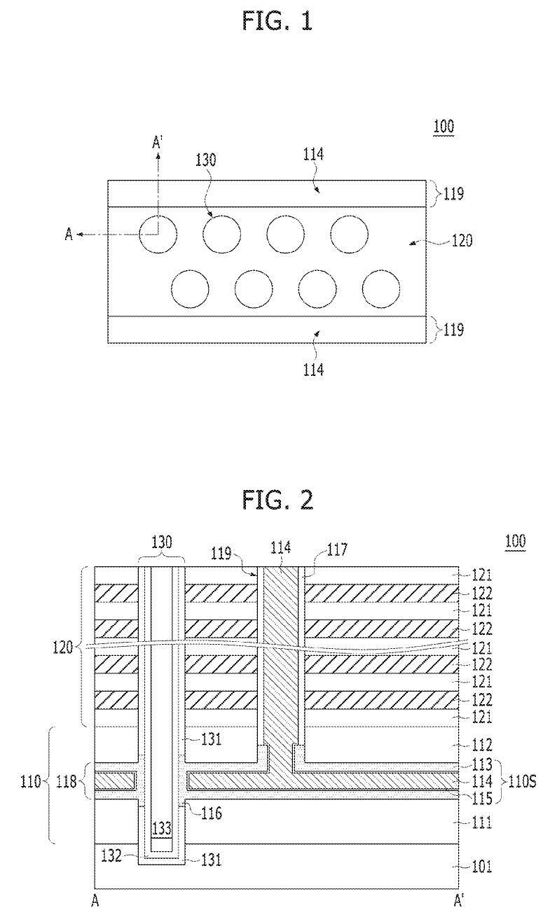

FIGS. 1 and 2 are views illustrating a vertical semiconductor device according to an embodiment. FIG. 2 is a cross-sectional view taken along line A-A' of FIG. 1.

Referring to FIGS. 1 and 2, a vertical semiconductor device 100 may include a semiconductor substrate 101, a lower level stack 110 formed on the semiconductor substrate 101, and an alternate stack 120 on the lower level stack 110. The lower level stack 110 may include source layers 111 and 112 and a source channel contact layer 110S.

The alternate stack 120 may include insulation layers 121 and gate electrodes 122 alternately formed with one another. The lowest insulation layer among the insulation layers 121 may be thicker than the other insulation layers. The insulation layers 121 may include silicon oxide, and the gate electrodes 122 may include a metal-base material. The gate electrodes 122 may include tungsten or a stack of titanium nitride and tungsten.

The vertical semiconductor device 100 may further include a vertical channel structure 130 penetrating the alternate stack 120. The vertical channel structure 130 may include a memory layer 131, a channel layer 132, and a core insulation layer 133. The core insulation layer 133 may fill the internal space of the channel layer 132, and the memory layer 131 may surround the outer wall of the channel layer 132. A lower portion of the vertical channel structure 130 may penetrate the lower level stack 110 and make contact with the semiconductor substrate 101. An upper portion of the vertical channel structure 130 may penetrate the alternate stack 120.

The vertical semiconductor device 100 may further include a slit 119 penetrating the alternate stack 120. The slit 119 may be spaced apart from the vertical channel structure 130. A sealing layer 117 may be formed on the side wall of the slit 119. The slit 119 may be shaped as a trench. The sealing layer 117 may cover first ends of the gate electrodes 122. The sealing layer 117 may include silicon oxide, silicon nitride, carbon-containing silicon oxide, or a combination thereof.

The lower level stack 110 is described below.

The lower level stack 110 may include the source layers 111 and 112 and the source channel contact layer 110S between the source layers 111 and 112. The source layers 111 and 112 may include a lower source layer 111 and an upper source layer 112. The lower level stack 110 may further include a horizontal recess 118. The horizontal recess 118 may be defined between the lower source layer 111 and the upper source layer 112. The source channel contact layer 110S may be formed between the lower source layer 111 and the upper source layer 112. The source channel contact layer 110S may fill the horizontal recess 118. The lower source layer 111 and the upper source layer 112 may include the same material, e.g., a semiconductor material, such as polysilicon. The source channel contact layer 110S may include a semiconductor material, e.g., silicon.

The source channel contact layer 110S may include a first silicon layer 113 and a second silicon layer 114. The first silicon layer 113 may cover the surface of the horizontal recess 118. The first silicon layer 113 may directly contact the channel layer 132 of the vertical channel structure 130. A portion of the first silicon layer 113 may extend to cover a bottom portion of the slit 119, contacting the sealing layer 117. The second silicon layer 114 may fill the horizontal recess 118 on the first silicon layer 113 and extend to fill the slit 119.

The first silicon layer 113 and the second silicon layer 114 may be silicon layers having different crystalline phases. The first silicon layer 113 may be a crystalline silicon layer, and the second silicon layer 114 may be an amorphous silicon layer. The first silicon layer 113 may be an epitaxial polysilicon layer, and the second silicon layer 114 may be an amorphous silicon layer. The first silicon layer 113 may be an epitaxial polysilicon layer, and the second silicon layer 114 may be a deposited amorphous silicon layer. The epitaxial polysilicon layer may be formed by epitaxial growth, and the deposited amorphous silicon layer may be formed by deposition. The first silicon layer 113 and the second silicon layer 114 may include a dopant. The dopant may include phosphorus. The first silicon layer 113 may include a phosphorus-doped epitaxial polysilicon layer, and the second silicon layer 114 may include a phosphorus-doped amorphous silicon layer.

The source channel contact layer 110S may further include an interface layer 115 between the first silicon layer 113 and the second silicon layer 114. The interface layer 115 may include silicon oxide. The interface layer 115 may include an oxide of the first silicon layer 113. The interface layer 115 may be thinner than the first silicon layer 113 and the second silicon layer 114. The interface layer 115 may serve to improve the surface roughness of the first silicon layer 113, thereby preventing seams or voids of the second silicon layer 114. The interface layer 115 may be extremely thin for electrical contact between the first silicon layer 113 and the second silicon layer 114.

As described above, the contact surface between the channel layer 132 and the first silicon layer 113 may include an oxide-free surface, and the contact surface between the first silicon layer 113 and the second silicon layer 114 may include an oxidized surface. The oxidized surface may include the interface layer 115. The oxide-free surface refers to a surface in which oxide is not present, and the surface of the channel layer 132 has a pre-cleaned surface, and the first silicon layer 113 may be selectively grown on the pre-cleaned surface.

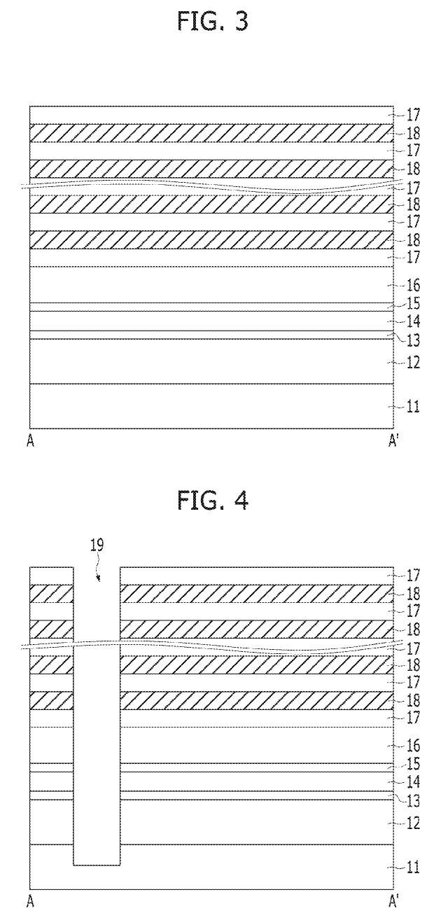

FIGS. 3, 4, 5, 6, 7, 8, 9, 10, 11, 12, 13, 14, 15, 16, and 17, are views illustrating an example method for manufacturing a vertical semiconductor device according to an embodiment. FIGS. 3 to 17 are cross-sectional views taken along line A-A' of FIG. 1.

As shown in FIG. 3, a stack structure including a lower source layer 12, an upper source layer 16, liner layers 13 and 15, and a source sacrificial layer 14 may be formed on a semiconductor substrate 11. The source sacrificial layer 14 may be formed between the lower source layer 12 and the upper source layer 16, and the liner layers 13 and 15 may be formed between the source sacrificial layer 14 and the lower/upper source layers 12 and 16. The lower source layer 12, the source sacrificial layer 14, and the upper source layer 16 may include the same material, and the liner layers 13 and 15 may include a material different from the lower source layer 12, the source sacrificial layer 14, and the upper source layer 16. The lower source layer 12, the source sacrificial layer 14, and the upper source layer 16 may have etch selectivity to the liner layers 13 and 15. The lower source layer 12, the source sacrificial layer 14, and the upper source layer 16 may include a semiconductor material, and the liner layers 13 and 15 may include an insulation material. The lower source layer 12, the source sacrificial layer 14, and the upper source layer 16 may include polysilicon, and the liner layers 13 and 15 may include silicon oxide. The liner layers 13 and 15 may be thinner than the lower source layer 12, the source sacrificial layer 14, and the upper source layer 16.

Next, an upper level stack including insulation layers 17 and sacrificial layers 18 may be formed on the upper source layer 16. The upper level stack may include the insulation layers 17 and the sacrificial layers 18 alternately stacked one over another. The insulation layers 17 and the sacrificial layers 18 may be stacked alternately several times. The insulation materials 17 and the sacrificial layers 18 may include different materials. The insulation layers 17 may have etch selectivity to the sacrificial layers 18. The insulation layers 17 may include silicon oxide, and the sacrificial layers 18 may include silicon nitride. The insulation layers 17 and the sacrificial layers 18 may have the same thickness. The insulation layers 17 and the sacrificial layers 18 may be thicker than the liner layers 13 and 15, and the insulation layers 17 and the sacrificial layers 18 may be thinner than the lower source layer 12 and the upper source layer 16. Among the insulation layers 17, the lowest insulation layer 17 may be thicker than the other insulation layers 17.

The insulation layers 17 and the sacrificial layers 18 may be formed using chemical vapor deposition (CVD) or atomic layer deposition (ALD).

Referring to FIG. 4, a vertical opening 19 may be formed. To form the vertical opening 19, the insulation layers 17, the sacrificial layers 18, the upper source layer 16, the liner layers 13 and 15, the source sacrificial layer 14, and the lower source layer 12 may be etched.

The vertical opening 19 may be formed to be perpendicular to the surface of the semiconductor substrate 11. The vertical opening 19 may be shaped to penetrate the insulation layers 17 and the sacrificial layers 18 and extend to penetrate the upper source layer 16, the liner layers 13 and 15, the source sacrificial layer 14, and the lower source layer 12. Although not shown, at plan view, a plurality of vertical openings 19 may be formed and may have a hole array structure. Upon forming the vertical opening 19, the surface of the semiconductor substrate 101 may be recessed. According to an embodiment, the vertical opening 19 may be denoted a 'vertical recess,' 'vertical hole,' or 'channel hole.'

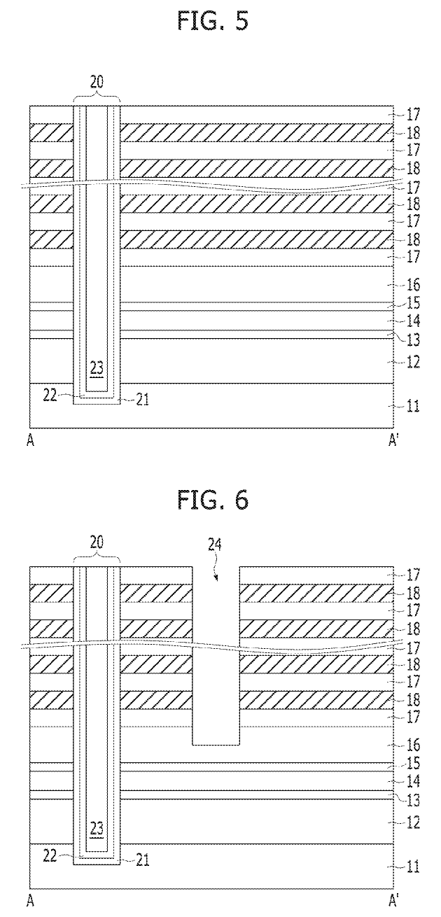

Referring to FIG. 5, a vertical channel structure 20 may be formed in the vertical opening 19. The vertical channel structure 20 may fill the vertical opening 19. The vertical channel structure 20 may be denoted a 'pillar structure.'

The vertical channel structure 20 may include a memory layer 21, a channel layer 22, and a core insulation layer 23. The memory layer 21 may have a stack structure including a blocking layer, a charge trapping layer, and a tunnel insulation layer. The blocking layer and the tunnel insulation layer may include oxide, and the charge trapping layer may include nitride. The memory layer 21 may have an oxide-nitride-oxide (ONO) structure. The channel layer 22 may include an undoped polysilicon layer without impurities. The channel layer 22 may have a cylinder shape having an inner space. The memory layer 21 may surround the outer wall of the channel layer 22. The internal space of the channel layer 22 may be fully filled with the core insulation layer 23. The core insulation layer 23 may include silicon oxide or silicon nitride.

Referring to FIG. 6, a slit 24 may be formed. The slit 24 may be formed by etching the insulation layers 17 and the sacrificial layers 18, and the slit 24 may extend downwards up to a portion of the upper source layer 16. The bottom surface of the slit 24 might not penetrate the upper source layer 16. The slit 24 may also be referred to as a trench. From a top view, the slit 24 may be shaped as a line extending in any one direction. The slit 24 may be formed to be perpendicular to the surface of the semiconductor substrate 11. The slit 24 may be referred to as a vertical slit.

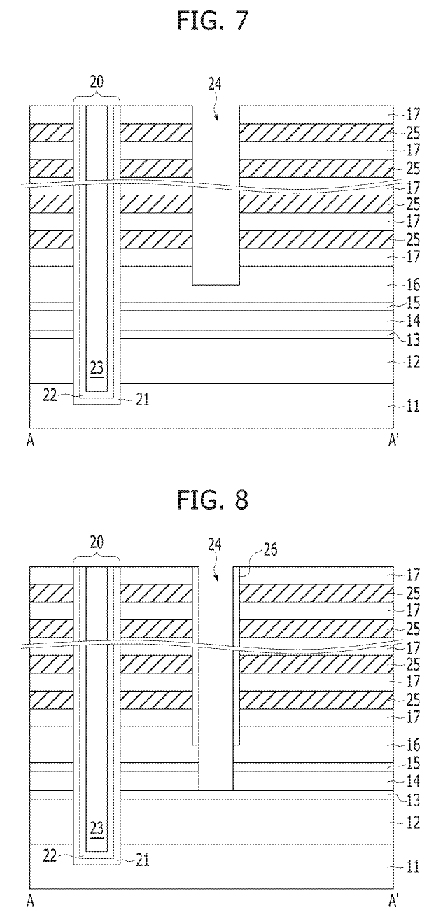

Referring to FIG. 7, the sacrificial layers 18 may be replaced with gate electrodes 25 via the slit 24. For example, after the sacrificial layers 18 are removed, the space resultant from removing the sacrificial layers 18 may be filled with the gate electrodes 25. The gate electrodes 25 may include tungsten, titanium nitride, or a combination thereof.

Referring to FIG. 8, the sealing layer 26 may be formed on the side wall of the slit 24. The sealing layer 26 may include at least one sealing material. The sealing layer 26 may include oxide, nitride, or a combination thereof. For example, the sealing layer 26 may include a stack of nitride-oxide-nitride, i.e., an NON structure. Subsequently, the sealing layer 26 may be etched to be left as spacers in both side walls of the slit 24.

Next, the upper source layer 16, liner layer 15, and source sacrificial layer 14 may be etched using the sealing layer 26 as a barrier. The liner layer 13 and the lower source layer 12 may be left without being etched out.

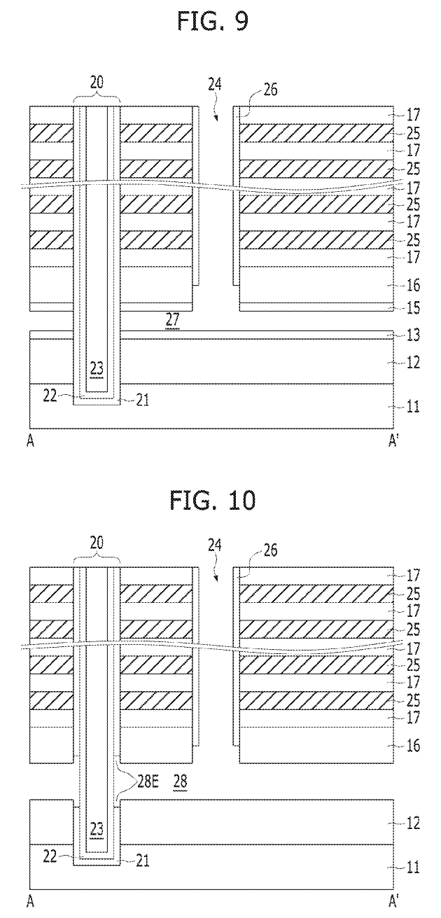

Referring to FIG. 9, the source sacrificial layer 14 may selectively be removed via the slit 24. Thus, a horizontal recess 27 may be formed. The horizontal recess 27 may extend from the slit 24. Since the horizontal recess 27 removes the source sacrificial layer 14 by a dip-out process, the horizontal recess 27 may be formed between the liner layers 13 and 15. The horizontal recess 27 may be parallel with the surface of the semiconductor substrate 11. When the source sacrificial layer 14 is removed, the liner layers 13 and 15 may remain unremoved due to etch selectivity. The horizontal recess 27 may be formed between the lower source layer 12 and the upper source layer 16. When the source sacrificial layer 14 is removed, the lower source layer 12 and the upper source layer 16 might not be removed. Wet etching may be applied to remove the source sacrificial layer 14. Since the source sacrificial layer 14 includes a polysilicon layer, wet etching may include a chemical for etching the polysilicon layer.

The horizontal recess 27 may expose a lower side wall of the vertical channel structure 20. The outer wall of the vertical channel structure 20 may be a portion of the memory layer 21. At top view, the horizontal recess 27 may be shaped to surround the lower side wall of the vertical channel structure 20.

Referring to FIG. 10, the liner layers 13 and 15 may be removed. Thus, the volume of the horizontal recess 27 may be increased. An enlarged horizontal recess 28 may be formed. Hereinafter, this is referred to as a horizontal recess 28.

After the liner layers 13 and 15 are removed, a portion of the memory layer 21 of the vertical channel structure 20 may be removed.

By the above-described series of processes, the horizontal recess 28 may expose the lower outer wall of the channel layer 22. A portion of the memory layer 21 may be cut by the horizontal recess 28. Thus, an undercut 28E may be formed between the channel layer 22 and the lower/upper source layers 12 and 16.

The horizontal recess 28 may be parallel with the semiconductor substrate 11 and have a first surface. The slit 24 may extend from the horizontal recess 28 and have a second surface perpendicular to the semiconductor substrate 11. In other words, a gapfill target structure including the horizontal recess 28 having the first surface and the slit 24 having the second surface may be formed on the semiconductor substrate 11. The first surface may be provided by the channel layer 22, lower source layer 12, and upper source layer 16, and the second surface may be provided by the sealing layer 26. The first surface may be a surface of a silicon layer, and the second surface may be a surface of an insulation material.

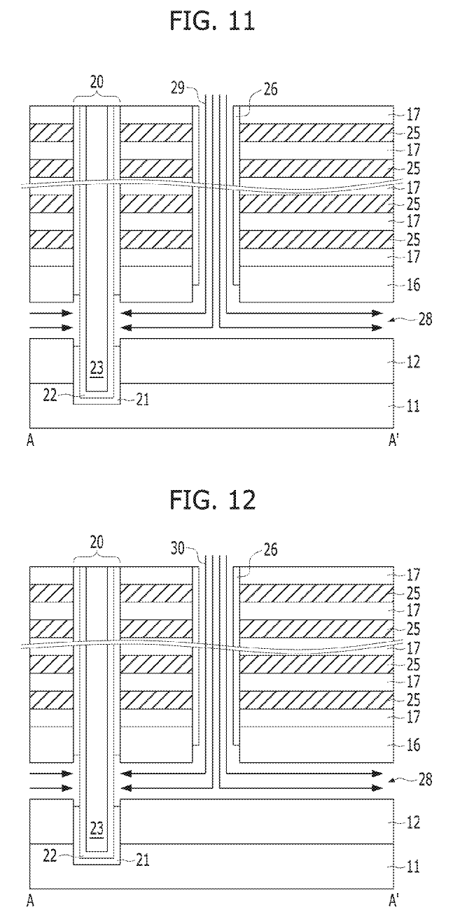

Subsequently, by the series of processes shown in FIGS. 11 to 17, the horizontal recess 28 and the slit 24 may be gap-filled with a semiconductor material.

Referring to FIG. 11, a pre-treatment process 29 may be performed. The pre-treatment process 29 may be performed before the semiconductor substrate 11 is loaded in a furnace chamber to form a source contact layer.

The pre-treatment process 29 may include a process for thinning or removing the native oxide remaining on the exposed surface of the channel layer 22. The pre-treatment process 29 may be performed using a fluorine-based chemical. After removing or thinning the native oxide as thin as possible, it needs to subsequently be loaded in the furnace chamber. The time taken from the pre-treatment process 29 to the loading of the substrate in the furnace chamber may be within two hours. The fluorine-based chemical may include NF₃ or HF.

Referring to FIG. 12, the pre-treated (29) semiconductor substrate 11 is loaded in the furnace chamber to deposit a source contact layer.

Next, a pre-cleaning process 30 may be performed, using an in-situ etching gas, in the furnace chamber. The native oxide on the surface of the channel layer 22, which is inevitably formed when moving and loading the substrate, may be removed by the pre-cleaning process 30. The etching gas for the pre-cleaning process 30 may include halogen gas, such as Cl or HBr. The removal of native oxide using the etching gas may be performed in such a manner that the etching gas infiltrates through tiny gaps present in the native oxide and etches the channel layer 22 and then lifts off the native oxide. Thus, if the time taken from the pre-treatment process 29 to the loading of the substrate into the furnace chamber increases, the tiny gaps in the native oxide may vanish, drastically lowering the in-situ etching efficiency. By the pre-cleaning process 30, the native oxide present on the exposed surface of the lower source layer 12 and the upper source layer 16 may be removed as well. The channel layer 22 may include the pre-cleaned surface that may be oxide-free. The exposed surface of the lower source layer 12 and the upper source layer 16 may also include the oxide-free, pre-cleaned surface.

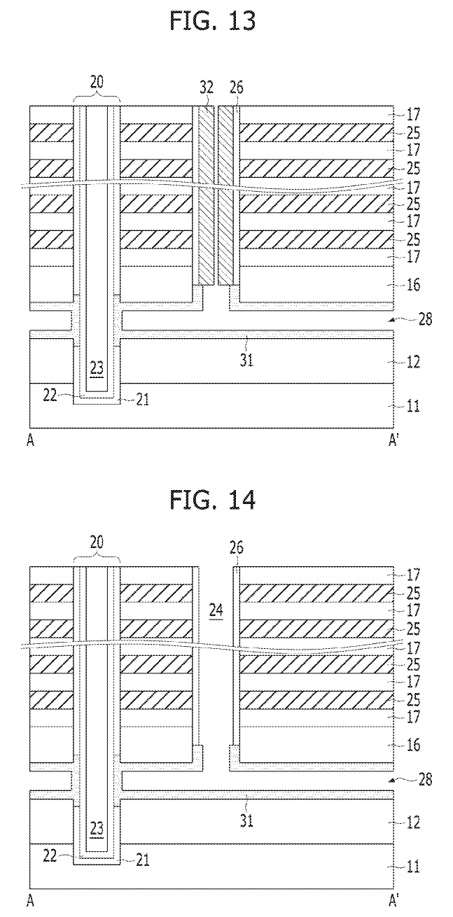

Referring to FIG. 13, source contact layers 31 and 32 may be formed. The source contact layers 31 and 32 may be deposited in-situ in the furnace chamber after the pre-cleaning process 30. The source contact layers 31 and 32 may be formed by depositing a first semiconductor material. The first semiconductor material may include a polysilicon layer 31. Upon forming the source contact layers 31 and 32, the polysilicon layer 31 may be selectively epitaxial-grown on the first surface, i.e., the exposed surface of the lower source layer 12, channel layer 22, and upper source layer 16. A sacrificial amorphous silicon layer 32 is grown on the amorphous material, such as silicon oxide or silicon nitride, i.e., the second surface. The polysilicon layer 31 may be an epitaxially grown polysilicon layer.

As such, the deposition process of the polysilicon layer 31 may selectively epitaxial-grow the polysilicon layer 31 on the exposed surface of the pre-cleaned channel layer 22 while simultaneously forming, selectively, the sacrificial amorphous silicon layer 32 on the surface of the sealing layer 26. The words “simultaneous” and “simultaneously” as used herein with respect to occurrences mean that the occurrences take place on overlapping intervals of time. For example, if a first occurrence takes place over a first interval of time and a second occurrence takes place simultaneously over a second interval of time, then the first and second intervals at least partially overlap each other such that there exists a time at which the first and second occurrences are both taking place.

The deposition process of the polysilicon layer 31 and the sacrificial amorphous silicon layer 32 may adjust the mixing ratio of a chlorine-containing silicon source material to a chlorine-free silicon source material, thereby adjusting the deposition ratio of the polysilicon layer 31 to the sacrificial amorphous silicon layer 32. The chlorine-containing silicon source material may include dichlorosilane (SiH₂Cl₂, DCS), and the chlorine-free silicon source material may include monosilane (SiH₄). The deposition process of the polysilicon layer 31 and the sacrificial amorphous silicon layer 32 may be performed, with the proportion of the chlorine-free silicon source material larger than the proportion of the chlorine-containing silicon source material.

The mixing ratio and pressure of dichlorosilane (DCS) and monosilane (SiH₄) may increase the growth rate of the polysilicon layer 31 to a level equal to that of the sacrificial amorphous silicon layer 32. For example, the process temperature may be 450°C to 490°C, the mixing ratio of monosilane to dichlorosilane may be 7:1 to 9:1, and the pressure may be set to less than 1 Torr.

If the proportion of dichlorosilane (DCS) increases, the formation rate of the polysilicon layer 31 is higher than that of the sacrificial amorphous silicon layer 32, but uniformity within the wafer may deteriorate.

If the proportion of monosilane (SiH₄) is increased, the uniformity in the wafer is improved, but the formation rate of the sacrificial amorphous silicon layer 32 is increased, and the inside of the slit 24 may be blocked. If the slit 24 is blocked, the polysilicon layer is difficult to form.

The pressure needs to be less than 1Torr to secure deposition uniformity in the wafer.

For example, when the ratio of monosilane (SiH₄) to dichlorosilane (DCS) is 3:1, the deposition ratio of the polysilicon layer 31 to the sacrificial amorphous silicon layer 32 may be about 1.5:1. In this case, the uniformity is about 5 to 9%(0.5Torr to 4.5Torr).

When the ratio of monosilane (SiH₄) to dichlorosilane (DCS) is 8:1, the deposition ratio of the polysilicon layer 31 to the sacrificial amorphous silicon layer 32 may be about 1.1:1, and the uniformity is about 2 to 4% (0.5Torr to 4.5Torr).

The deposition ratio of the polysilicon layer 31 to the sacrificial amorphous silicon layer 32 according to the gas ratio may be maintained in pressure changes ranging from 0.5 Torr to 4.5 Torr.

The principle of adjusting the deposition ratio of the polysilicon layer 31 to the sacrificial amorphous silicon layer 32 according to the ratio of monosilane (SiH₄) to dichlorosilane (DCS) is as follows. Cl₂ gas generated from dichlorosilane (DCS) may play a role to suppress formation of the sacrificial amorphous silicon layer 32 (or etching simultaneously with deposition). As the amount of Cl₂ gas increases, the deposition rate of the sacrificial amorphous silicon layer 32 decreases, but the deposition of the polysilicon layer 31 might not be suppressed. Resultantly, the difference in thickness between the polysilicon layer 31 and the sacrificial amorphous silicon layer 32 may be adjusted according to the proportion of dichlorosilane (DCS).

Meanwhile, as the proportion of dichlorosilane (DCS) increases, the thickness distribution is deteriorated. Therefore, the ratio of monosilane (SiH₄) to dichlorosilane (DCS) may be set to 8:1, improving the thickness distribution. Further, the deposition ratio of the polysilicon layer 31 to the sacrificial amorphous silicon layer 32 may be optimized by setting the ratio of monosilane (SiH₄) to dichlorosilane (DCS) to 8:1.

As described above, the polysilicon layer 31 is deposited on the surface of the horizontal recess 28 using a mixed gas of monosilane (SiH₄) and dichlorosilane (DCS), and the sacrificial amorphous silicon layer 32 is rendered to be deposited on the sealing layer 26 by optimizing the mixing ratio of monosilane (SiH₄) to dichlorosilane (DCS).

A broken silicon lattice may exist on the surfaces of the channel layer 22, the lower source layer 12, and the upper source layer 16 from which the native oxides have been removed by the pre-cleaning process 30 using a halogen gas. Accordingly, since the energy of growth in the crystalline direction is low, the polysilicon layer 31 is epitaxially grown on the surfaces of the channel layer 22, the lower source layer 12 and the upper source layer 16.

The polysilicon layer 31 may be thinner than the sacrificial amorphous silicon layer 32. The sacrificial amorphous silicon layer 32 might not fully fill the inside of the slit 24. The polysilicon layer 31 and the sacrificial amorphous silicon layer 32 may have the same thickness.

In another embodiment, the deposition process of the polysilicon layer 31 and the sacrificial amorphous silicon layer 32 may be performed using mono silane (SiH₄) alone.

Referring to FIG. 14, the sacrificial amorphous silicon layer 32 may be selectively removed. The sacrificial amorphous silicon layer 32 may be removed using HBr gas. The sacrificial amorphous silicon layer 32 may be completely removed from the slit 24. During the etching process using HBr gas, the sacrificial amorphous silicon layer 32 may have an etching rate that is about 10 times or more faster than that of the polysilicon layer 31.

For example, when the sacrificial amorphous silicon layer 32 is grown to about 400 Å and the polysilicon layer 31 is grown to about 250 Å, the polysilicon layer 32 may be etched by 400 Å while etching the sacrificial amorphous silicon layer 32 by 400 Å using HBr gas. Resultantly, after the sacrificial amorphous silicon layer 32 is fully removed, the polysilicon layer 31 may be left with a thickness of 210Å.

As such, after the sacrificial amorphous silicon layer 32 is fully removed, the polysilicon layer 31 may remain. The polysilicon layer 31 may remain in the horizontal recess 28.

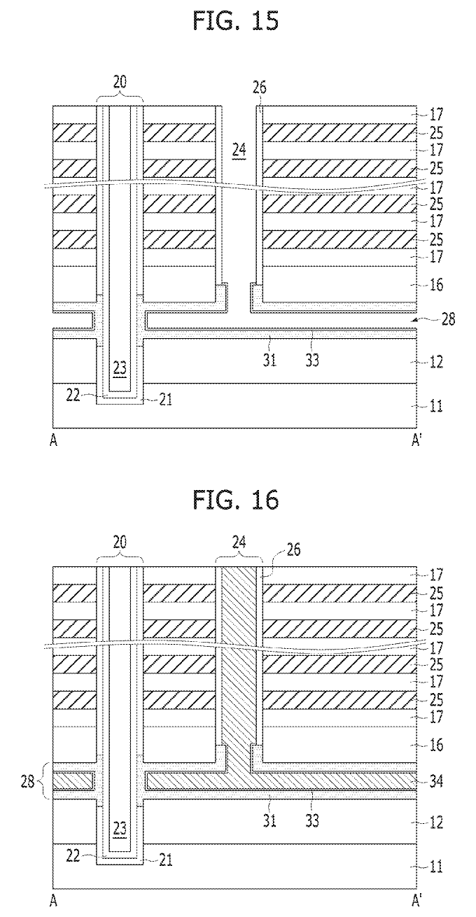

Referring to FIG. 15, an interface layer 33 may be formed. The interface layer 33 may be formed by oxidizing the surface of the polysilicon layer 31. The interface layer 33 may include silicon oxide. The interface layer 33 may be thinner than the polysilicon layer 31. The interface layer 33 may play a role to improve the surface roughness of the polysilicon layer 31.

Referring to FIG. 16, a second semiconductor material may be formed on the interface layer 33, filling the slit 24. The second semiconductor material may include the amorphous silicon layer 34. The amorphous silicon layer 34 may be formed by deposition. After the interface layer 33 is formed, the amorphous silicon layer 34 is formed. Thus, seams or voids may be prevented upon depositing the amorphous silicon layer 34. The interface layer 33 may be extremely thin for electrical contact between the polysilicon layer 31 and the amorphous silicon layer 34. The polysilicon layer 31 and the amorphous silicon layer 34 may include a dopant. The dopant may include phosphorus. The polysilicon layer 31 may include a phosphorus-doped epitaxial polysilicon layer, and the amorphous silicon layer 34 may include a phosphorus-doped amorphous silicon layer.

By the above-described series of processes, the horizontal recess 28 may be void-free and be filled with the polysilicon layer 31, interface layer 33, and amorphous silicon layer 34. The slit 24 may be filled with the amorphous silicon layer 34. A portion of the polysilicon layer 31 may extend to cover a bottom portion of the slit 24, contacting the bottom surface of the sealing layer 26. The amorphous silicon layer 34 may fill the horizontal recess 28 and extend to fill the slit 24. The contact surface between the polysilicon layer 31 and the amorphous silicon layer 34 may include the interface layer 33, and the interface layer 33 may include oxide.

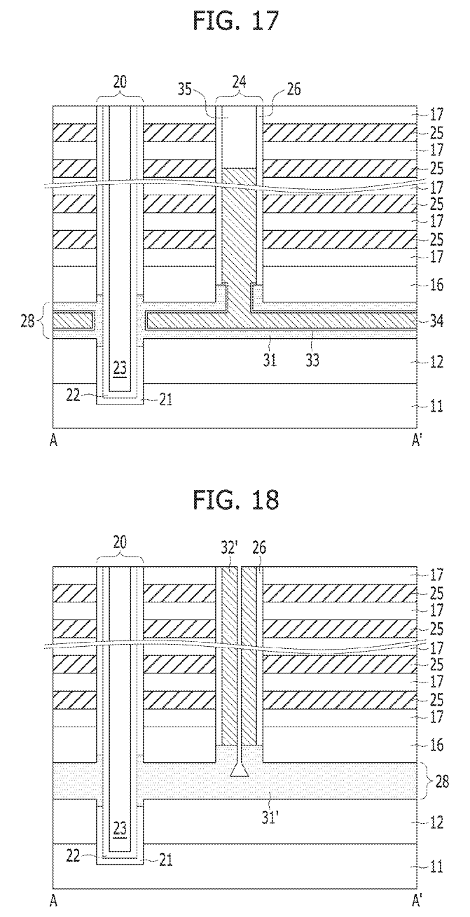

Referring to FIG. 17, after the amorphous silicon layer 34 is recessed to a predetermined depth, it may be filled with a metal-based material 35. The metal-based material 35 may include tungsten, titanium nitride, or a combination thereof.

FIGS. 18, 19, 20, and 21 are views illustrating a method for manufacturing a vertical semiconductor device according to an embodiment. In FIGS. 18 to 21, the same reference numbers are used to denote the same elements as those in FIGS. 3 to 17. No detailed description is given of duplicate elements.

First, the horizontal recess 28 may be formed by a series of processes as shown in FIGS. 3 to 12. Then, the pre-treatment process 29 and the pre-cleaning process 30 may be performed.

Next, as shown in FIG. 18, source contact layers may be formed. The source contact layers may be deposited in-situ in the furnace chamber after the pre-cleaning process 30. The source contact layers may include the polysilicon layer 31'. Upon forming the source contact layers, the polysilicon layer 31' may be epitaxially grown on the exposed surface of the lower source layer 12, channel layer 22, and upper source layer 16. However, a sacrificial amorphous silicon layer 32' is grown on the amorphous materials, such as silicon oxide or silicon nitride. The polysilicon layer 31' may fully fill the horizontal recess 28. The sacrificial amorphous silicon layer 32' might not be formed in the horizontal recess 28. The sacrificial amorphous silicon layer 32' may be selectively formed on the sealing layer 26.

As such, if the horizontal recess 28 is fully filled with the polysilicon layer 31', the process is simplified.

The description made above in connection with FIG. 13 may be applied to the deposition process of the polysilicon layer 31' and the sacrificial amorphous silicon layer 32'. For example, the deposition process of the polysilicon layer 31' and the sacrificial amorphous silicon layer 32' may be performed using a mixed gas of a chlorine-containing silicon source material and a chlorine-free silicon source material. The chlorine-containing silicon source material may include dichlorosilane (SiH₂Cl₂, DCS), and the chlorine-free silicon source material may include monosilane (SiH₄). The deposition process of the polysilicon layer 31' and the sacrificial amorphous silicon layer 32' may be performed, with the proportion of the chlorine-free silicon source material larger than the proportion of the chlorine-containing silicon source material.

The mixing ratio and pressure of dichlorosilane (DCS) and monosilane (SiH₄) may increase the growth rate of the polysilicon layer 31' to a level equal to that of the sacrificial amorphous silicon layer 32'. For example, the process temperature may be 450°C to 490°C, the mixing ratio of monosilane to dichlorosilane may be 7:1 to 9:1, and the pressure may be set to less than 1 Torr.

As described above, the polysilicon layer 31' is deposited on the surface of the horizontal recess 28 using a mixed gas of monosilane (SiH₄) and dichlorosilane (DCS), and the sacrificial amorphous silicon layer 32' is rendered to be deposited on the sealing layer 26 by optimizing the mixing ratio of monosilane (SiH₄) to dichlorosilane (DCS).

In another embodiment, the deposition process of the polysilicon layer 31' and the sacrificial amorphous silicon layer 32' may be performed using mono silane (SiH₄) alone.

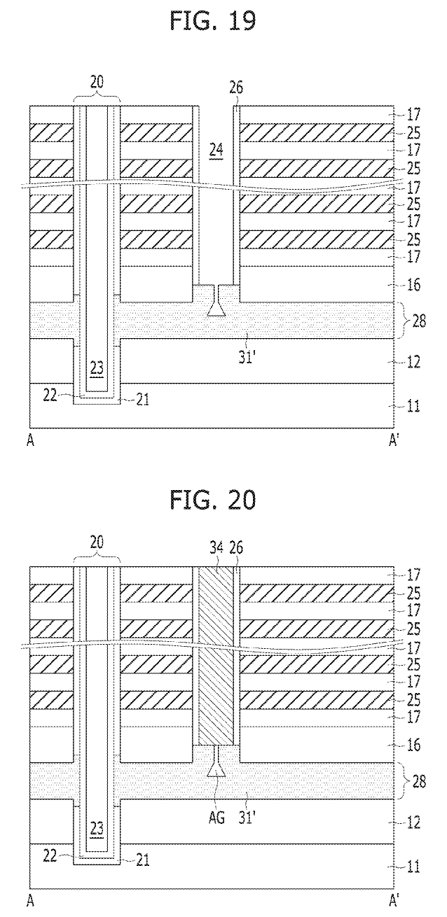

Referring to FIG. 19, the sacrificial amorphous silicon layer 32' may be selectively removed. The sacrificial amorphous silicon layer 32' may be removed using HBr gas.

After the sacrificial amorphous silicon layer 32' is removed, the polysilicon layer 31' may remain in the horizontal recess 28. The polysilicon layer 31' may fill the horizontal recess 28.

Referring to FIG. 20, an amorphous silicon layer 34' may be formed on the polysilicon layer 31', filling the slit 24. The amorphous silicon layer 34' may be formed by deposition. The polysilicon layer 31' and the amorphous silicon layer 34' may include a dopant. The dopant may include phosphorus. The polysilicon layer 31' may include a phosphorus-doped epitaxial polysilicon layer, and the amorphous silicon layer 34' may include a phosphorus-doped amorphous silicon layer.

An air gap AG may be formed between the polysilicon layer 31' and the amorphous silicon layer 34'. Alternatively, the air gap AG may be filled with the amorphous silicon layer 34'.

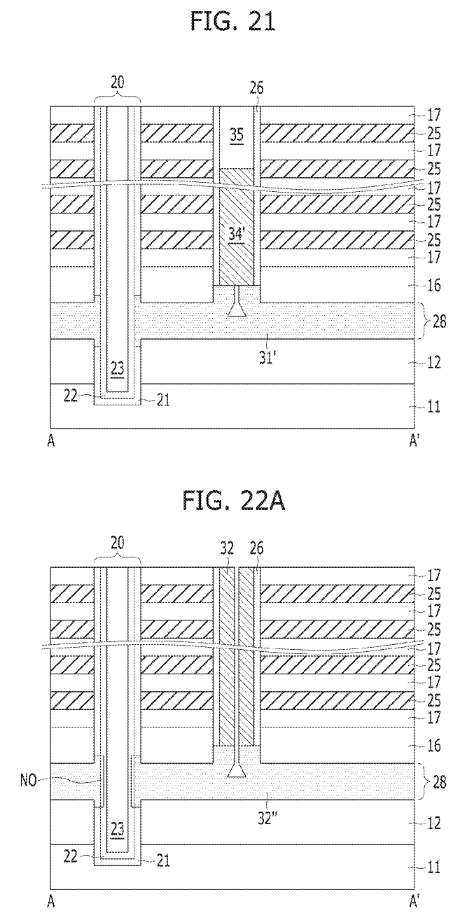

Referring to FIG. 21, after the amorphous silicon layer 34' is recessed to a predetermined depth, it may be filled with a metal-based material 35. The metal-based material 35 may include tungsten, titanium nitride, or a combination thereof.

According to the above-described embodiments, since native oxides are removed by the pre-cleaning process 30 using halogen gas, phosphorus (Ph) diffused from the polysilicon layers 31 and 31' may be easily controlled. Thus, a NAND operation, in particular an erase operation using gate induced drain leakage (GIDL) current may be smoothly performed.

Further, since the native oxides are removed by the pre-cleaning process 30 using halogen gas, current inhibitors between the channel layer 22 and the polysilicon layers 31 and 31' may be freed, rendering it possible to secure a high and uniform current.

Further, since the polysilicon layers 31 and 31' and the sacrificial amorphous silicon layers 32 and 32' are selectively formed, a relatively high etch rate may be secured as compared with the other part of the polysilicon layers 31 and 31' when a subsequent etching process proceeds. Thus, it is easy to secure an etch margin in the subsequent etching process.

Since it is easy to secure an etching margin, the incidence of defective etching of the polysilicon layers 31 and 31' due to the etching process may be reduced. For example, use of a combination of the polysilicon layer 31 and the sacrificial amorphous silicon layer 32 may further reduce defects.

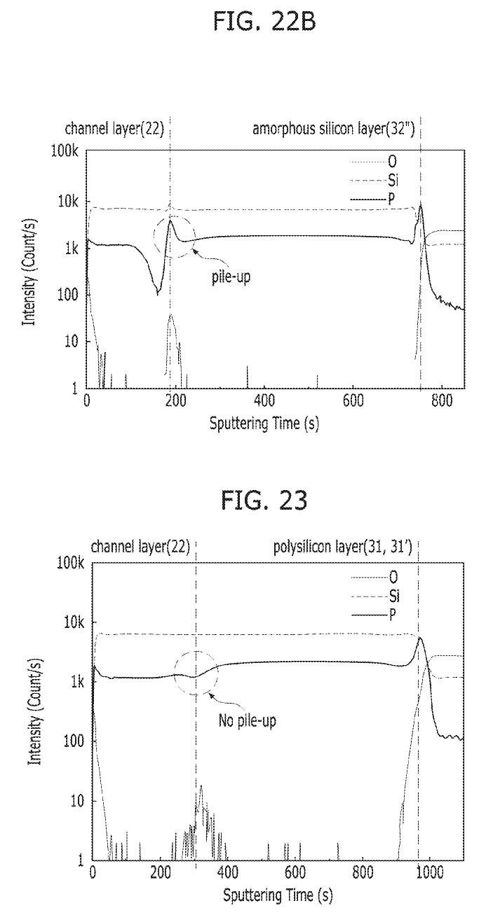

FIG. 22A is a view illustrating a method for manufacturing a vertical semiconductor device according to a comparative example. In the comparative example, the cleaning process 30 of FIG. 12 is omitted.

Referring to FIG. 22A, a polysilicon layer may be deposited as a source contact layer. However, as native oxides NO are on the surface of the channel layer 22, an amorphous silicon layer 34" may be deposited earlier than a polysilicon layer. The amorphous silicon layer 34" may fill the horizontal recess 28.

FIG. 22B shows the results of secondary ion mass spectrometry (SIMS) analysis according to the comparative example. A phosphorous (P) pile-up may occur on the interface surface between the channel layer 22 and the amorphous silicon layer 34" due to the native oxides NO.

FIG. 23 shows the results of SIMS analysis according to embodiments. No phosphorous pile-up occurs on the interface surface between the channel layer 22 and the polysilicon layers 31 and 31'.

In another embodiment, a selective polysilicon layer deposition process may be applied to drain contact layers, as well as to the source channel contact layers.

In another embodiment, a selective polysilicon layer deposition process is a low-temperature process (450℃ to 490℃) as compared with normal epitaxy processes and be applied in low-temperature epitaxy processes.

As another embodiment, since the selective polysilicon layer deposition process is able to adjust the ratio of polysilicon layer to amorphous silicon layer, it is also applicable to hard mask processes of amorphous silicon layer/polysilicon layer that requires a difference in light transmittance. By using the nature that the transmittance of polysilicon layer is higher than the transmittance of amorphous silicon layer, a hard mask may be formed so that areas may be differentiated by partial amorphous and crystalline formation. For example, to form the vertical opening 19 of FIG. 4, the hard mask layer may be used in which case the hard mask layer may be formed using the selective polysilicon layer deposition process of FIG. 13. In other words, the hard mask layer may include a stack of polysilicon layer and amorphous silicon layer, and the stack of polysilicon layer and amorphous silicon layer may be deposited using a mixed gas of monosilane and dichlorosilane.

While the present invention has been described with respect to specific embodiments, it will be apparent to those skilled in the art that various changes and modifications may be made without departing from the spirit and scope of the invention as defined in the following claims.

What is claimed is:

1. A vertical semiconductor device, comprising:
an alternate stack including insulation layers and gate electrodes alternately stacked one over another, over a semiconductor substrate;
a source channel contact layer between the semiconductor substrate and the alternate stack;
a vertical channel layer penetrating the alternate stack and the source channel contact layer; and
a memory layer between the vertical channel layer and the alternate stack, wherein
the source channel contact layer includes:
an epitaxial polysilicon layer contacting the vertical channel layer; and
an amorphous silicon layer over the epitaxial polysilicon layer.

2. The vertical semiconductor device of claim 1, wherein a contact surface between the vertical channel layer and the epitaxial polysilicon layer includes an oxide-free surface, and a contact surface between the epitaxial polysilicon layer and the amorphous silicon layer includes an oxidized surface.

3. The vertical semiconductor device of claim 1, wherein the source channel contact layer further includes a silicon oxide layer between the epitaxial polysilicon layer and the amorphous silicon layer.

4. The vertical semiconductor device of claim 1, wherein the source channel contact layer further includes a lower source polysilicon layer and an upper source polysilicon layer positioned to provide a horizontal recess between the semiconductor substrate and the alternate stack, and wherein
the epitaxial polysilicon layer extends to contact the lower source polysilicon layer and the upper source polysilicon layer.

5. The vertical semiconductor device of claim 4, wherein a stack of the epitaxial polysilicon layer and the amorphous silicon layer fills a horizontal recess between the lower source polysilicon layer and the upper source polysilicon layer.

6. The vertical semiconductor device of claim 4, wherein the epitaxial polysilicon layer fills a horizontal recess between the lower source polysilicon layer and the upper source polysilicon layer, and wherein the amorphous silicon layer is positioned perpendicular to the epitaxial polysilicon layer.

7. The vertical semiconductor device of claim 6, further comprising an air gap between the epitaxial polysilicon layer and the amorphous silicon layer.

8. The vertical semiconductor device of claim 1, further comprising a slit spaced apart in parallel from the vertical channel layer and penetrating the alternate stack, wherein a portion of the source channel contact layer extends to be positioned in the slit.

9. A vertical semiconductor device, comprising:
a semiconductor substrate;
a lower level stack formed on the semiconductor substrate;
an alternate stack including insulation layers and gate electrodes alternately stacked one over another, on the lower level stack; and
a vertical channel structure penetrating the alternate stack and the lower level stack,
wherein the lower level stack incudes
a lower source layer;
an upper source layer;
a horizontal recess defined between the lower source layer and the upper source layer; and
a source channel contact layer between the lower source layer and the upper source layer, and fills the horizontal recess.

10. The vertical semiconductor device of claim 9, wherein the lowest insulation layer among the insulation layers is thicker than the other insulation layers.

11. The vertical semiconductor device of claim 9, wherein the insulation layers include silicon oxide, and the gate electrodes include a metal-base material such as tungsten or a stack of titanium nitride and tungsten.

12. The vertical semiconductor device of claim 9, wherein the lower source layer and the upper source layer include the same material such as polysilicon.

13. The vertical semiconductor device of claim 9, wherein a lower portion of the vertical channel structure penetrates the lower level stack and contacts with the semiconductor substrate, and an upper portion of the vertical channel structure penetrates the alternate stack.

14. The vertical semiconductor device of claim 9, further comprising:
a slit penetrating the alternate stack and being spaced apart from the vertical channel structure; and
a sealing layer formed on the side wall of the slit and being shaped as a trench.

15. The vertical semiconductor device of claim 14, wherein the sealing layer covers first ends of the gate electrodes, and includes silicon oxide, silicon nitride, carbon-containing silicon oxide, or a combination thereof.

16. The vertical semiconductor device of claim 14, wherein the vertical channel structure includes
a channel layer;
a memory layer that surrounds an outer wall of the channel layer; and
a core insulation layer that fills an internal space of the channel layer.

17. The vertical semiconductor device of claim 16, wherein the source channel contact layer includes
a first silicon layer that covers a surface of the horizontal recess, directly contacts the channel layer of the vertical channel structure, and extends to cover a bottom portion of the slit, contacting the sealing layer; and
a second silicon layer that fills the horizontal recess on the first silicon layer and extends to fill the slit.

18. The vertical semiconductor device of claim 17, wherein the first silicon layer is an epitaxial polysilicon layer formed by epitaxial growth, and the second silicon layer is a deposited amorphous silicon layer formed by deposition.

19. The vertical semiconductor device of claim 16, wherein the source channel contact layer further includes
an interface layer formed between the first silicon layer and the second silicon layer and including silicon oxide,
wherein the interface layer is thinner than the first silicon layer and the second silicon layer.

20. The vertical semiconductor device of claim 19, wherein a contact surface between the channel layer and the first silicon layer includes an oxide-free surface, and the second silicon layer includes an oxidized surface.
